(19) United States
(12) Patent Application Publication
(10) Pub. No.: US 2025/0174433 A1
(43) Pub. Date: May 29, 2025

(54) METHOD OF PROCESSING A SUBSTRATE

(71) Applicant: SAMSUNG ELECTRONICS CO,.LTD., Suwon-si (KR)

(72) Inventors: Donghyeon NA, Suwon-si (KR); Minyoung Hur, Suwon-si (KR); Kyung-sun Kim, Suwon-si (KR); Nam Kyun Kim, Suwon-si (KR); Sung-Yeol Kim, Suwon-si (KR); Hyun Bae Kim, Suwon-si (KR); Hwasoo Seok, Suwon-si (KR); Seungbo Shim, Suwon-si (KR); Sungyong Lim, Suwon-si (KR)

(73) Assignee: SAMSUNG ELECTRONICS CO,.LTD., Suwon-si (KR)

(21) Appl. No.: 18/758,153

(22) Filed: Jun. 28, 2024

(30) Foreign Application Priority Data
Nov. 24, 2023 (KR) 10-2023-0165381

(51) Int. Cl. H01J 37/32

(52) U.S. Cl. CPC H01J 37/32146; H01J 37/32541; H01J 37/32642

(57) ABSTRACT

A method of processing a substrate is provided. The method includes providing the substrate on a stage of a substrate processing apparatus; and processing the substrate on the stage. The processing of the substrate includes: providing source power to the substrate processing apparatus; and providing bias power to the substrate processing apparatus. The providing of the bias power to the substrate processing apparatus includes: providing a first non-sinusoidal wave to a plasma electrode of the stage; and providing a second non-sinusoidal wave to an edge electrode of the stage. A duty ratio of the second non-sinusoidal wave is different from a duty ratio of the first non-sinusoidal wave.

### CROSS-REFERENCE TO RELATED APPLICATION

This application claims priority to Korean Patent Application No. 10-2023-0165381, filed on Nov. 24, 2023, in the Korean Intellectual Property Office, the disclosure of which is incorporated by reference herein in its entirety.

### BACKGROUND

The present disclosure relates to a method of processing a substrate, and more particularly, to a method of processing a substrate in which plasma on an edge region is independently controlled.

A semiconductor device may be manufactured by various processes. For example, a semiconductor device may be manufactured by performing a photolithography process, an etching process, a deposition process, a plating process, etc., on a substrate. Plasma may be used in the etching process and the deposition process. Radiofrequency (RF) power may be applied to a substrate processing apparatus to generate and/or control the plasma. The behavior of the plasma may vary depending on the form of the RF power.

### SUMMARY

One or more example embodiments provide a method of processing a substrate, which is capable of controlling plasma on an edge region.

One or more example embodiments may also provide a method of processing a substrate, which is capable of controlling a density of plasma on a central region and a density of plasma on an edge region independently of each other.

One or more example embodiments may further provide a method of processing a substrate, which is capable of improving a yield of an etching process performed on a substrate.

According to an aspect of an example embodiment, a method of processing a substrate includes: providing the substrate on a stage of a substrate processing apparatus; and processing the substrate on the stage. The processing of the substrate includes: providing source power to the substrate processing apparatus; and providing bias power to the substrate processing apparatus. The providing of the bias power to the substrate processing apparatus includes: providing a first non-sinusoidal wave to a plasma electrode of the stage; and providing a second non-sinusoidal wave to an edge electrode of the stage. A duty ratio of the second non-sinusoidal wave is different from a duty ratio of the first non-sinusoidal wave.

According to another aspect of an example embodiment, a method of processing a substrate includes: providing the substrate on a stage of a substrate processing apparatus; providing source power to the substrate processing apparatus as a first macro pulse; providing a first non-sinusoidal wave having a first micro pulse to the substrate processing apparatus; and providing a second non-sinusoidal wave having a second micro pulse to the substrate processing apparatus. A duty ratio of the second micro pulse is less than a duty ratio of the first micro pulse.

According to another aspect of an example embodiment, a method of processing a substrate includes: providing source power to a substrate processing apparatus; providing a first non-sinusoidal wave to the substrate processing apparatus; and providing a second non-sinusoidal wave to the substrate processing apparatus. The first non-sinusoidal wave includes: a first on-period in which a first voltage is applied to the substrate processing apparatus; and a first off-period in which a second voltage is applied to the substrate processing apparatus. The second non-sinusoidal wave includes: a second on-period in which a third voltage is applied to the substrate processing apparatus; and a second off-period in which a fourth voltage is applied to the substrate processing apparatus. The first on-period includes the second on-period.

### BRIEF DESCRIPTION OF DRAWINGS

The above and other aspects and features will be more apparent from the following description of example embodiments, taken in conjunction with the accompanying drawings, in which:

FIG. 1 is a cross-sectional view illustrating a substrate processing apparatus according to some example embodiments;

FIG. 2 is an enlarged cross-sectional view of a substrate processing apparatus according to some example embodiments;

FIG. 3 is a flow chart illustrating a method of processing a substrate according to some example embodiments;

FIGS. 4 to 8 are views illustrating a method of processing a substrate according to some example embodiment;

FIG. 9 is a graph showing power applied to a substrate processing apparatus in a method of processing a substrate according to some example embodiments;

FIG. 10 is a graph showing first bias power applied to a substrate processing apparatus in a method of processing a substrate according to some example embodiments; and

FIG. 11 is a graph showing second bias power applied to a substrate processing apparatus in a method of processing a substrate according to some example embodiments.

### DETAILED DESCRIPTION

Hereinafter, example embodiments will be described in detail with reference to the accompanying drawings. The same reference numerals or the same reference designators may denote the same components or elements throughout the specification. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

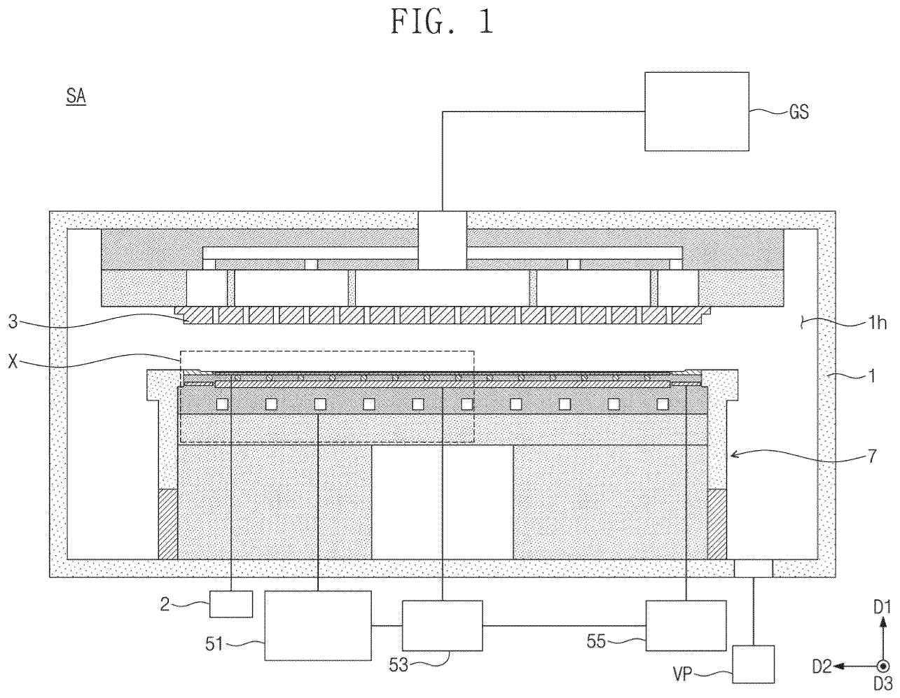

FIG. 1 is a cross-sectional view illustrating a substrate processing apparatus according to some example embodiments.

In the drawings, a reference designator D1 may indicate a first direction, a reference designator D2 may indicate a second direction intersecting the first direction, and a reference designator D3 may indicate a third direction intersecting both the first direction D1 and the second direction D2. The first direction D1 may be referred to as a vertical direction. In addition, each of the second direction D2 and the third direction D3 may be referred to as a horizontal direction.

Referring to FIG. 1, a substrate processing apparatus SA may be provided. The substrate processing apparatus SA may be an apparatus used to perform a process on a substrate by using plasma. More particularly, the substrate processing apparatus SA may be an apparatus used to perform an etching process on a substrate by using the plasma. The term ‘substrate’ may indicate a silicon (Si) wafer, but example embodiments are not limited thereto. The substrate processing apparatus SA may be configured to generate the plasma by at least one of various methods. For example, the substrate processing apparatus SA may be a capacitively coupled plasma (CCP) apparatus and/or an inductively coupled plasma (ICP) apparatus. As an example, the substrate processing apparatus SA will be described as a CCP apparatus for the purpose of ease and convenience in explanation and illustration. The substrate processing apparatus SA may include a process chamber 1, a stage 7, a shower head 3, a direct current (DC) power supply 2, a source power supply 51, a first bias power supply 53, a second bias power supply 55, a vacuum pump VP, and a gas supply GS.

The process chamber 1 may provide a process space 1h. A process may be performed on a substrate provided in the process space 1h. The process space 1h may be separated from an external space. While the process is performed on the substrate, the process space 1h may be in a substantial vacuum state. The process chamber 1 may have, but is not limited to, a cylindrical shape.

The stage 7 may be located in the process chamber 1. In this regard, the stage 7 may be located in the process space 1h. The stage 7 may be configured to support and/or hold the substrate. In a state in which the substrate is placed on the stage 7, the process may be performed on the substrate. The stage 7 will be described below in more detail.

The shower head 3 may be located in the process chamber 1. In this regard, the shower head 3 may be located in the process space 1h. The shower head 3 may be spaced apart from the stage 7 and may be above the stage 7. A gas supplied from the gas supply GS may be uniformly supplied into the process space 1h through the shower head 3.

The DC power supply 2 may be configured to apply DC power to the stage 7. The substrate may be fixed or held at a certain position on the stage 7 by the DC power applied from the DC power supply 2.

The source power supply 51 may be configured to apply source power to the stage 7. More particularly, the source power supply 51 may apply the source power in the form of radiofrequency (RF) power to the stage 7. Thus, the plasma may be generated in the process space 1h. This will be described below in more detail.

The first bias power supply 53 may be configured to apply first bias power to the stage 7. More particularly, the first bias power supply 53 may apply power in the form of a non-sinusoidal wave to the stage 7. For example, the first bias power supply 53 may apply power in the form of a square wave to the stage 7. By controlling application of the power by the first bias power supply 53, the plasma in the process space 1h may be controlled. This will be described below in more detail.

The second bias power supply 55 may be configured to apply second bias power to the stage 7. More particularly, the second bias power supply 55 may apply power in the form of a non-sinusoidal wave to the stage 7. For example, the second bias power supply 55 may apply power in the form of a square wave to the stage 7. By controlling application of the power by the second bias power supply 55, the plasma in the process space 1h may be controlled. This will be described below in more detail.

The vacuum pump VP may be connected to the process space 1h. While the process is performed on the substrate, a vacuum pressure may be applied to the process space 1h by the vacuum pump VP.

The gas supply GS may be configured to supply a gas into the process space 1h. To achieve this, the gas supply GS may include a gas tank, a compressor, and a valve. A portion of the gas supplied into the process space 1h by the gas supply GS may be formed into the plasma.

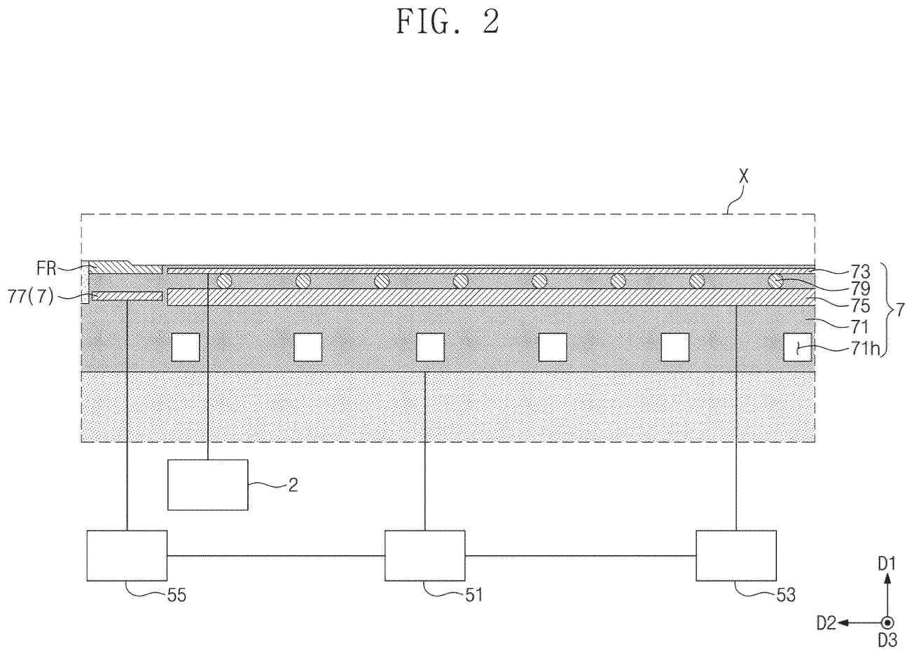

FIG. 2 is an enlarged cross-sectional view of a region ‘X’ of FIG. 1 according to some example embodiments.

Referring to FIG. 2, the stage 7 may be configured to fix or hold the substrate at a certain position by using electrostatic force. In this regard, the stage 7 may include an electrostatic chuck (ESC). The stage 7 may include a chuck body 71, a chuck electrode 73, a plasma electrode 75, an edge electrode 77, and a heater 79.

The substrate may be provided on the chuck body 71. The chuck body 71 may fix or hold the substrate at a certain position. The chuck body 71 may have a cylindrical shape. The chuck body 71 may include, but is not limited to, ceramics. The substrate may be provided on a top surface of the chuck body 71. A focus ring FR and/or an edge ring may surround the chuck body 71. Alternatively, the focus ring FR and/or the edge ring may be located on the chuck body 71. The chuck body 71 may define one or more cooling holes 71h. Cooling water may flow through the cooling hole 71h. The cooling water in the cooling hole 71h may absorb heat from the chuck body 71.

The chuck electrode 73 may be located in the chuck body 71. The chuck electrode 73 may be located above the plasma electrode 75. DC power may be applied to the chuck electrode 73. More particularly, the DC power supply 2 may be configured to apply the DC power to the chuck electrode 73. The substrate on the chuck body 71 may be fixed or held at a certain position by the DC power applied to the chuck electrode 73. The chuck electrode 73 may include, but is not limited to, aluminum (Al).

The plasma electrode 75 may be located in the chuck body 71. The plasma electrode 75 may include aluminum (Al). The plasma electrode 75 may have a disc shape, but example embodiments are not limited thereto. Source power and/or bias power may be applied to the plasma electrode 75. More particularly, the source power and/or the first bias power may be applied to the plasma electrode 75. For this, the plasma electrode 75 may be electrically connected to the first bias power supply 53. This will be described below in more detail.

The edge electrode 77 may surround the plasma electrode 75. The edge electrode 77 may have a ring shape. The edge electrode 77 may be located under the focus ring FR. The edge electrode 77 may include aluminum (Al), but example embodiments are not limited thereto. Source power and/or bias power may be applied to the edge electrode 77. More particularly, the source power and/or the second bias power may be applied to the edge electrode 77. For this, the edge electrode 77 may be electrically connected to the second bias power supply 55. This will be described below in more detail.

The heater 79 may be located in the chuck body 71. The heater 79 may be located between the chuck electrode 73 and the plasma electrode 75. The heater 79 may include a heating wire. For example, the heater 79 may include concentric heating wires. The heater 79 may emit heat, and may be used to increase a temperature of the chuck body 71.

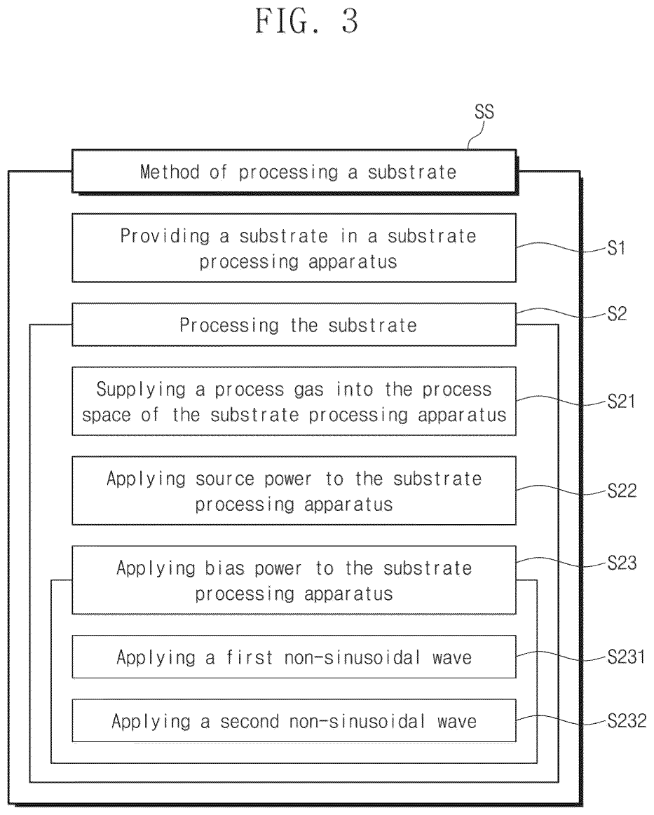

FIG. 3 is a flow chart illustrating a method of processing a substrate according to some example embodiments.

Referring to FIG. 3, a method of processing a substrate (SS) may be provided. The method of processing a substrate (SS) may be performed using the substrate processing apparatus SA described with reference to FIGS. 1 and 2. The method of processing a substrate (SS) may include providing a substrate in a substrate processing apparatus (S1) and processing the substrate (S2).

The processing of the substrate (S2) may include supplying a process gas into the process space of the substrate processing apparatus (S21), applying source power to the substrate processing apparatus (S22), and applying bias power to the substrate processing apparatus (S23).

The applying of the bias power to the substrate processing apparatus (S23) may include applying a first non-sinusoidal wave (S231) and applying a second non-sinusoidal wave (S232).

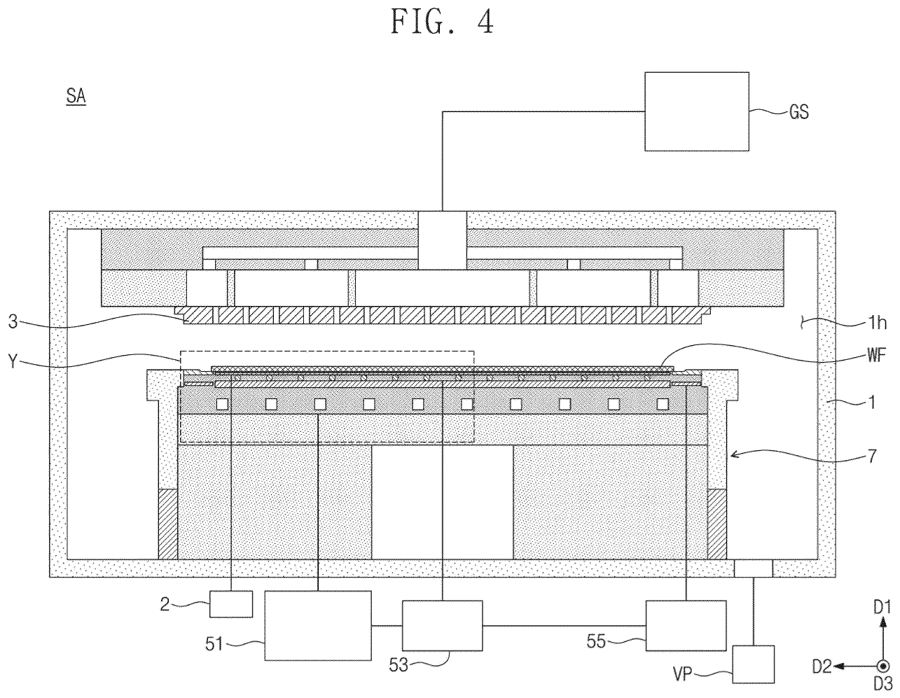

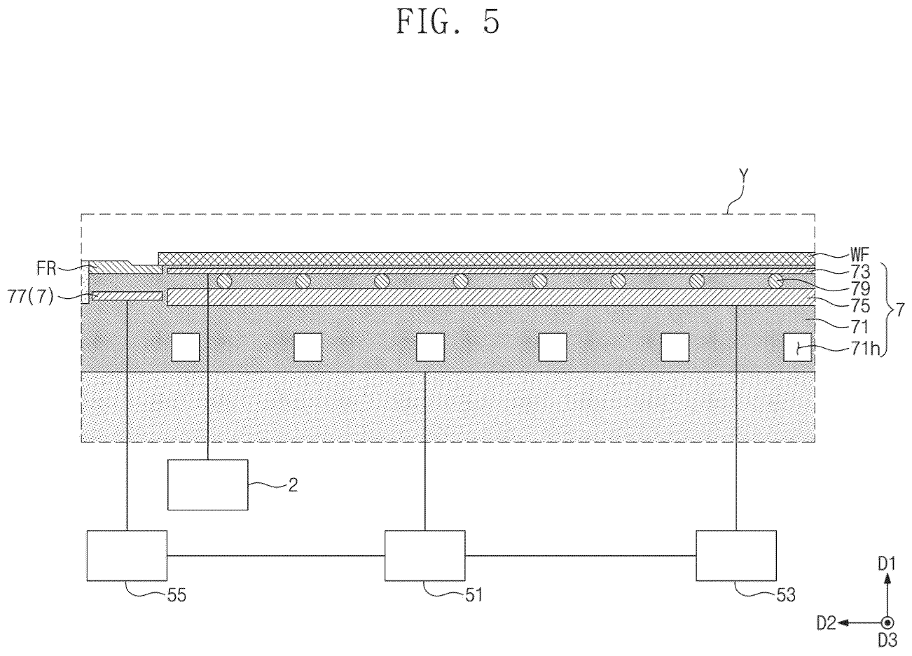

Hereinafter, a method of processing a substrate (SS) will be described in more detail with reference to FIGS. 4 to 8.

FIGS. 4 to 8 are views illustrating a method of processing a substrate according to some example embodiments, and may correspond to the flow chart of FIG. 3.

Referring to FIGS. 3, 4 and 5, the providing the substrate in the substrate processing apparatus (S1) may include providing a substrate WF on the stage 7. The substrate WF may be provided on the top surface of the chuck body 71. When the DC power (e.g., a DC voltage) is applied from the DC power supply 2 to the chuck electrode 73, the substrate WF may be fixed or held at a certain position on the stage 7 by the electrostatic force.

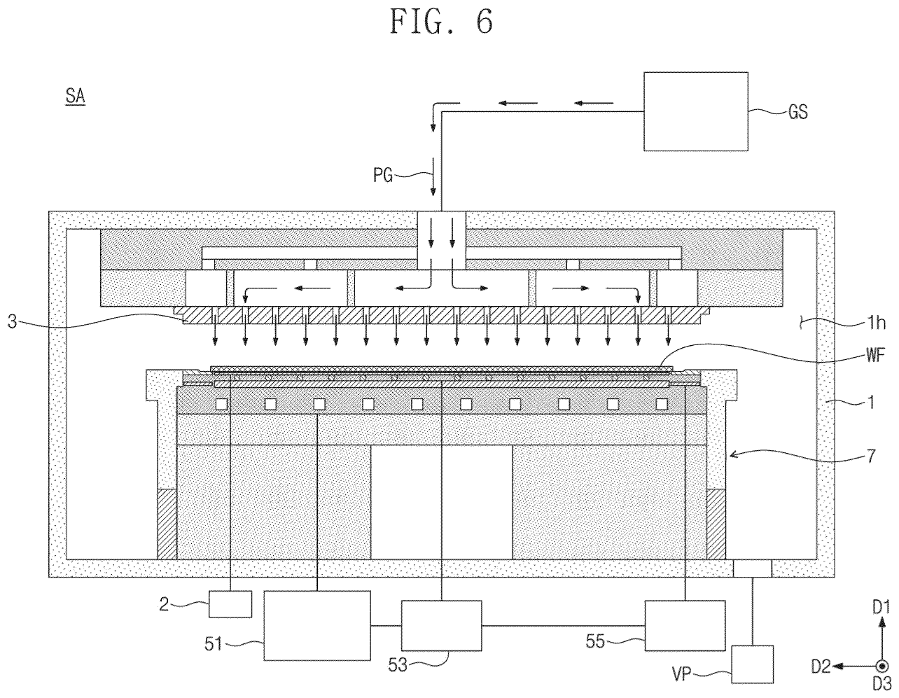

Referring to FIGS. 3 and 6, the supplying of the process gas (S21) may include supplying a process gas PG into the process chamber 1 by the gas supply GS. The process gas PG supplied from the gas supply GS may be dispersed into the process space 1h of the process chamber 1 through the shower head 3, and then may be provided onto the substrate WF.

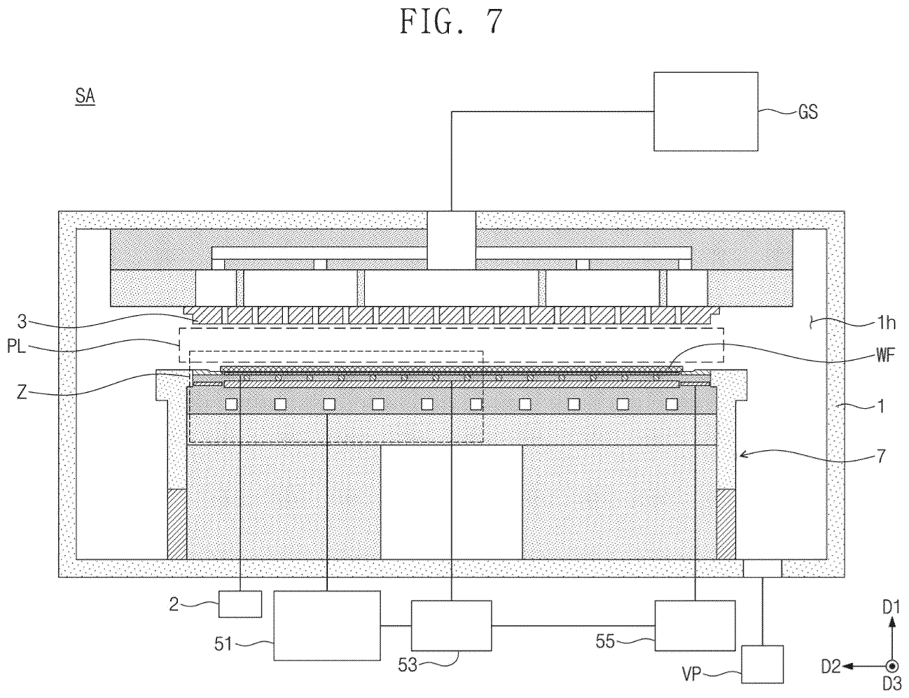

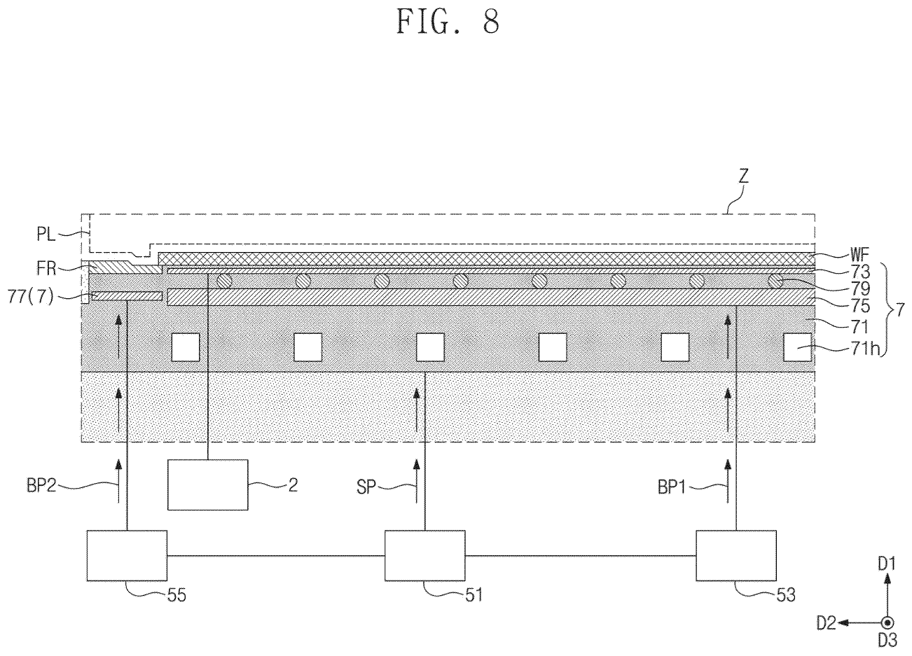

FIG. 8 is an enlarged cross-sectional view of a region ‘Z’ of FIG. 7 according to some example embodiments. Referring to FIGS. 3, 7 and 8, the applying of the source power to the substrate processing apparatus (S22) may include applying source power SP to the stage 7 by the source power supply 51. When the source power SP is applied to the stage 7, plasma PL may be generated in the process space 1h. The source power SP may be a sinusoidal wave. More particularly, the source power SP may be RF power. For example, a frequency of the source power SP may range from about 20 MHz to about 80 MHz, but example embodiments are not limited thereto. The source power SP may be supplied in the form of a first macro pulse. In this regard, the RF power having the frequency of about 20 MHz to about 80 MHz may be supplied in the form of the first macro pulse. This will be described below in more detail.

The applying of the first non-sinusoidal wave (S231) may include applying a first non-sinusoidal wave BP1 to the plasma electrode 75 by the first bias power supply 53. By controlling the first non-sinusoidal wave BP1 applied to the plasma electrode 75, the plasma PL in the process space 1h may be controlled. The first non-sinusoidal wave BP1 may have a first micro pulse. The first non-sinusoidal wave BP1 may be supplied in the form of a second macro pulse. In this regard, the first non-sinusoidal wave BP1 having the first micro pulse may be supplied in the form of the second macro pulse. This will be described below in more detail.

The applying of the second non-sinusoidal wave (S232) may include applying a second non-sinusoidal wave BP2 to the edge electrode 77 by the second bias power supply 55. By controlling the second non-sinusoidal wave BP2 applied to the edge electrode 77, the plasma PL in the process space 1h may be controlled. More particularly, when the second non-sinusoidal wave BP2 is applied to the edge electrode 77, the plasma PL in an edge region of the process space 1h may be controlled. The edge region of the process space 1h may indicate a region on the focus ring FR, but example embodiments are not limited thereto. The second non-sinusoidal wave BP2 may have a second micro pulse. The second non-sinusoidal wave BP2 may be supplied in the form of the second macro pulse. In this regard, the second non-sinusoidal wave BP2 having the second micro pulse may be supplied in the form of the second macro pulse. This will be described below in more detail.

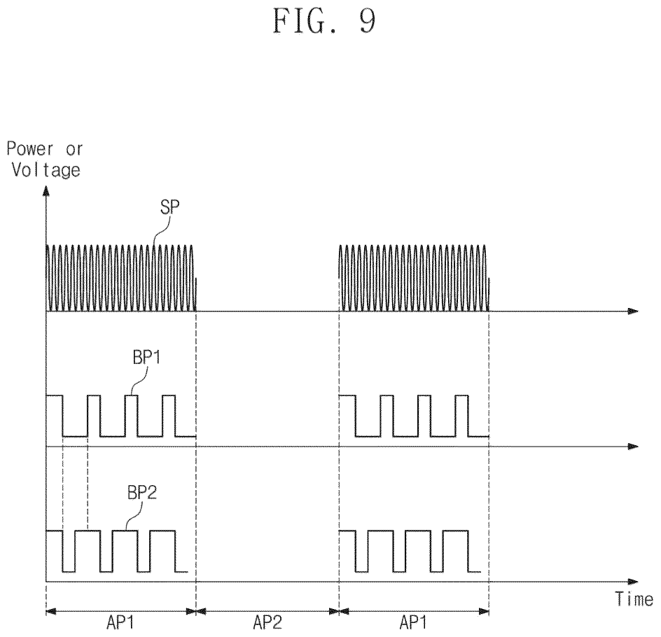

FIG. 9 is a graph showing powers applied to a substrate processing apparatus in a method of processing a substrate according to one or more example embodiments, and may correspond to FIG. 3.

Referring to FIG. 9, a horizontal axis may represent a time. A vertical axis may represent power or a voltage.

The source power SP, which as discussed above may be RF power having a frequency within a range of about 20 MHz to about 80 MHz, may be supplied in the form of the first macro pulse. The first macro pulse may have a form in which a macro on-duration AP1 (in which the RF power is emitted) and a macro off-duration AP2 (in which the RF power is not emitted) are repeated.

Each of the first non-sinusoidal wave (i.e., first bias power) BP1 and the second non-sinusoidal wave (i.e., second bias power) BP2, which as discussed above may be square waves, may be supplied in the form of the second macro pulse. The second macro pulse may be substantially the same as or substantially similar to the first macro pulse. For example, the second macro pulse may have a form in which the macro on-duration AP1 (in which the first non-sinusoidal wave BP1 and the second non-sinusoidal wave BP2 are supplied) and the macro off-duration AP2 (in which the first non-sinusoidal wave BP1 and the second non-sinusoidal wave BP2 are not supplied) are repeated.

Referring to FIGS. 3 and 9, the applying of the source power to the substrate processing apparatus (S22), the applying of the first non-sinusoidal wave (S231) and the applying of the second non-sinusoidal wave (S232) may be performed at the same time, but example embodiments are not limited thereto.

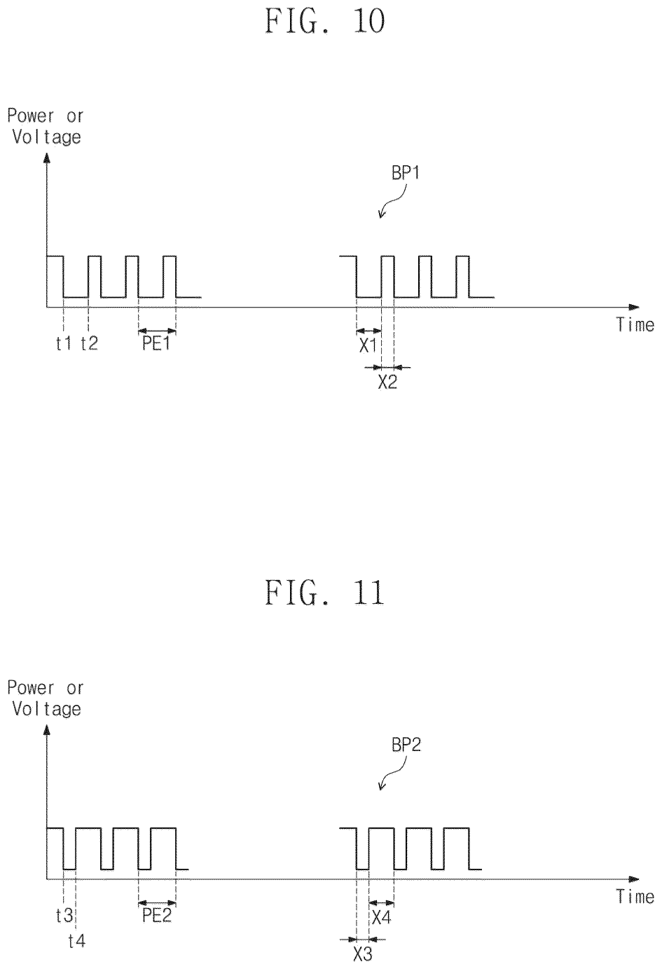

FIGS. 10 and 11 are graphs showing first and second bias power according to some example embodiments. FIG. 10 is a graph showing first bias power applied to the substrate processing apparatus in the method of processing a substrate according to the flow chart of FIG. 3, and FIG. 11 is a graph showing second bias power applied to the substrate processing apparatus in the method of processing a substrate according to the flow chart of FIG. 3.

Referring to FIG. 10, the first non-sinusoidal wave BP1 may be a non-sinusoidal wave in the form of the first micro pulse in which a first on-duration X1 and a first off-duration X2 are repeatedly performed. A frequency of the first micro pulse may range from about 200 kHz to about 600 kHz. The first on-duration X1 may be a duration in which a negative voltage is applied. The voltage applied in the first on-duration X1 may be referred to as a first voltage. In this regard, the first voltage may be the negative voltage. A sum of a single first on-duration X1 and a single first off-duration X2 may be referred to as a first period PE1. In this regard, the first period PE1 may be a sum of a duration time of the single first on-duration X1 and a duration time of the single first off-duration X2.

Referring to FIG. 11, the second non-sinusoidal wave BP2 may be a non-sinusoidal wave in the form of the second micro pulse in which a second on-duration X3 and a second off-duration X4 are repeatedly performed. A frequency of the second micro pulse may range from about 200 kHz to about 600 kHz. The second on-duration X3 may be a duration in which a negative voltage is applied. The voltage applied in the second on-duration X3 may be referred to as a second voltage. In this regard, the second voltage may be the negative voltage. A sum of a single second on-duration X3 and a single second off-duration X4 may be referred to as a second period PE2. In this regard, the second period PE2 may be a sum of a duration time of the single second on-duration X3 and a duration time of the single second off-duration X4.

Referring to FIGS. 10 and 11, the first period PE1 may be substantially the same as or substantially similar to the second period PE2. In this regard, the period of the first micro pulse may be substantially the same as or substantially similar to the period of the second micro pulse.

A duty ratio (or duty cycle) of the first non-sinusoidal wave BP1 may be constant over time. In this regard, a ratio of the first on-duration X1 and the first off-duration X2 may not change over time. In addition, a duty ratio of the second non-sinusoidal wave BP2 may be constant over time. In this regard, a ratio of the second on-duration X3 and the second off-duration X4 may not change over time.

The duty ratio of the first non-sinusoidal wave BP1 may be different from the duty ratio of the second non-sinusoidal wave BP2. In this regard, the ratio of the second on-duration X3 and the second off-duration X4 may be different from the ratio of the first on-duration X1 and the first off-duration X2. For example, the duty ratio of the second non-sinusoidal wave BP2 may be less than the duty ratio of the first non-sinusoidal wave BP1. By differently controlling the duty ratios of the first and second non-sinusoidal waves BP1 and BP2, the plasma PL (see FIG. 8) on the plasma electrode 75 (see FIG. 8) and the plasma PL on the edge electrode 77 (see FIG. 8) may be controlled differently from each other. In this regard, the plasma PL on the central region and the plasma PL on the edge region may be separately controlled.

Referring to FIGS. 9, 10 and 11, the second on-duration X3 may overlap in time with the first on-duration X1. For example, the second on-duration X3 may be included in the first on-duration X1. More particularly, a start time point t3 of the second on-duration X3 may be the same as or later than a start time point t1 of the first on-duration X1. An end time point t4 of the second on-duration X3 may be the same as or earlier than an end time point t2 of the first on-duration X1.

Each of the duty ratio of the first non-sinusoidal wave BP1 and the duty ratio of the second non-sinusoidal wave BP2 is constant over time in the above example embodiments, but example embodiments are not limited thereto. In certain example embodiments, the duty ratio of the second non-sinusoidal wave BP2 may change over time. For example, the duty ratio of the second non-sinusoidal wave BP2 may decrease or increase over time. Alternatively, the voltage of the second non-sinusoidal wave BP2 may change over time.

According to methods of processing a substrate according to example embodiments, the plasma on the edge region may be precisely controlled. More particularly, the plasma on the central region and the plasma on the edge region may be controlled independently of each other. Thus, a density of the plasma on the edge region may be separately adjusted. As a result, the etching process performed on the edge region of the substrate may be precisely controlled. In this regard, a yield of the etching process of the substrate may be improved.

According to methods of processing a substrate according to example embodiments, the plasma on the edge region may be controlled.

According to methods of processing a substrate according to example embodiments, the density of the plasma on the central region and the density of the plasma on the edge region may be controlled independently of each other.

According to methods of processing a substrate according to example embodiments, the yield of the etching process performed on the substrate may be improved.

While aspects of example embodiments have been particularly shown and described, it will be understood that various changes in form and details may be made therein without departing from the spirit and scope of the following claims.

The invention claimed is:

1. A method of processing a substrate, the method comprising:
providing the substrate on a stage of a substrate processing apparatus; and
processing the substrate on the stage,
wherein the processing of the substrate comprises:
providing source power to the substrate processing apparatus; and
providing bias power to the substrate processing apparatus,
wherein the providing of the bias power to the substrate processing apparatus comprises:
providing a first non-sinusoidal wave to a plasma electrode of the stage; and
providing a second non-sinusoidal wave to an edge electrode of the stage, and
wherein a duty ratio of the second non-sinusoidal wave is different from a duty ratio of the first non-sinusoidal wave.

2. The method of claim 1, wherein the edge electrode has a ring shape surrounding the plasma electrode.

3. The method of claim 1, wherein the substrate processing apparatus further comprises a focus ring surrounding the substrate provided on the stage, and
wherein the edge electrode is located under the focus ring.

4. The method of claim 1, wherein each of the first non-sinusoidal wave and the second non-sinusoidal wave is a square wave.

5. The method of claim 1, wherein a frequency of a micro pulse of the second non-sinusoidal wave ranges from 200 kHz to 600 kHz.

6. The method of claim 1, wherein a micro pulse of the first non-sinusoidal wave and a micro pulse of the second non-sinusoidal wave have a common period.

7. The method of claim 1, wherein a period of the first non-sinusoidal wave comprises:
a first on-duration in which a first voltage is applied to the plasma electrode; and
a first off-duration in which a second voltage is applied to the plasma electrode,
wherein a period of the second non-sinusoidal wave comprises:
a second on-duration in which a third voltage is applied to the edge electrode; and
a second off-duration in which a fourth voltage is applied to the edge electrode,
wherein the second voltage is a negative voltage, and
wherein the duty ratio of the second non-sinusoidal wave is less than the duty ratio of the first non-sinusoidal wave.

8. The method of claim 1, wherein each of the duty ratio of the first non-sinusoidal wave and the duty ratio of the second non-sinusoidal wave is constant.

9. The method of claim 8, wherein a period of the first non-sinusoidal wave comprises:
a first on-duration in which a first voltage is applied to the plasma electrode; and
a first off-duration in which a second voltage is applied to the plasma electrode,
wherein a period of the second non-sinusoidal wave comprises:
a second on-duration in which a third voltage is applied to the edge electrode; and
a second off-duration in which a fourth voltage not applied to the edge electrode, and
wherein the second on-duration overlaps in time with the first on-duration.

10. The method of claim 9, wherein the second on-duration starts with or later than the first on-duration, and
wherein the second on-duration ends with or before the first on-duration.

11. The method of claim 1, wherein the providing of the second non-sinusoidal wave comprises changing the duty ratio or a peak amplitude of the second non-sinusoidal wave over time.

12. The method of claim 1, wherein the providing of the source power to the substrate processing apparatus comprises providing the source power to the stage.

13. A method of processing a substrate, the method comprising:
providing the substrate on a stage of a substrate processing apparatus;
providing source power to the substrate processing apparatus as a first macro pulse;
providing a first non-sinusoidal wave having a first micro pulse to the substrate processing apparatus; and
providing a second non-sinusoidal wave having a second micro pulse to the substrate processing apparatus,
wherein a duty ratio of the second micro pulse is less than a duty ratio of the first micro pulse.

14. The method of claim 13, wherein a period in which the first non-sinusoidal wave is provided corresponds to a period in which the second non-sinusoidal wave is provided.

15. The method of claim 13, wherein a frequency of the first micro pulse ranges from 200 kHz to 600 kHz.

16. The method of claim 13, wherein the first micro pulse and the second micro pulse have a common period.

17. The method of claim 13, wherein the providing of the source power, the providing of the first non-sinusoidal wave and the providing of the second non-sinusoidal wave are concurrently performed.

18. The method of claim 13, wherein the providing of the source power comprises providing a sinusoidal wave to the substrate processing apparatus, and
wherein a frequency of the sinusoidal wave ranges from 20 MHz to 80 MHz.

19. The method of claim 13, wherein the providing of the first non-sinusoidal wave comprises providing the first non-sinusoidal wave to a plasma electrode of the substrate processing apparatus, and
wherein the providing of the second non-sinusoidal wave comprises providing the second non-sinusoidal wave to an edge electrode of the substrate processing apparatus.

20. A method of processing a substrate, the method comprising:
providing source power to a substrate processing apparatus;
providing a first non-sinusoidal wave to the substrate processing apparatus; and
providing a second non-sinusoidal wave to the substrate processing apparatus,
wherein the first non-sinusoidal wave comprises:
a first on-period in which a first voltage is applied to the substrate processing apparatus; and
a first off-period in which a second voltage is applied to the substrate processing apparatus,
wherein the second non-sinusoidal wave comprises:
a second on-period in which a third voltage is applied to the substrate processing apparatus; and
a second off-period in which a fourth voltage is applied to the substrate processing apparatus,
wherein the first on-period comprises the second on-period.

21-25. (canceled)
